(19) United States
(12) Patent Application Publication
(10) Pub. No.: US 2020/0127239 A1
(43) Pub. Date: Apr. 23, 2020

(54) DISPLAY PANEL, METHOD OF MANUFACTURING THE SAME AND DISPLAY MODULE HAVING THE SAME

(71) Applicant: Wuhan China Star Optoelectronics Semiconductor Display Technology Co., Ltd., Wuhan, Hubei (CN)

(72) Inventor: Bo WANG, Wuhank, Hubei (CN)

(73) Assignee: Wuhan China Star Optoelectronics Semiconductor Display Technology Co., Ltd., Wuhan, Hubei (CN)

(21) Appl. No.: 16/317,570

(22) PCT Filed: Nov. 15, 2018
(86) PCT No.: PCT/CN2018/115541

§ 371 Date: Jan. 14, 2019

(30) Foreign Application Priority Data
Sep. 26, 2018 (CN) 201811120294.6

(51) Int. Cl. H01L 51/56; H01L 51/52; H01L 27/32

(52) U.S. Cl. CPC H01L 51/56; H01L 51/5209; H01L 51/5221; H01L 2227/323; H01L 27/323; H01L 51/5237; H01L 27/3244

(57) ABSTRACT

A display panel, a method of manufacturing the same, and a display module having the same are provided. The display panel includes a light emitting device layer. The light emitting device layer includes an anode layer. The anode layer includes at least one metal layer. The at least one metal layer of the anode layer includes at least two different kinds of metal grains.

### BACKGROUND OF THE INVENTION

### Field of Invention

The disclosure relates to a technology, and more particularly to a display panel, a method of manufacturing the same, and a display module having the same.

### Description of Prior Art

Transparent conductive oxide (TCO) has high optical transparency in the visible region and low resistivity similar to metal. Therefore, it is widely used in different optoelectronic fields, such as ultraviolet detectors, solar cells, organic light emitting diodes (OLEDs) and liquid crystal displays.

In the prior art, indium tin oxide (ITO) having excellent electrical and optical properties is mainly used as the conductive oxide. However, due to the high cost and toxicity, researchers are looking for a better alternative to ITO.

Aluminum-doped zinc oxide (AZO) has the characteristics of low cost, wide band gap, non-toxicity, and high transparency, etc., and is considered to be the most likely material to replace ITO, but the manufacturing process of aluminum-doped zinc oxide is more complicated. Moreover, the use of AZO in place of the material of the anode layer in the OLED makes the OLED have lower luminous efficiency and shorter lifetime.

Therefore, there is a need to provide a display panel to solve the above problems.

### SUMMARY OF THE INVENTION

In view of the above, the disclosure provides a display panel, a method of manufacturing the same, and a display module having the same. The problem of lower luminous efficiency of OLED can be solved.

In order to achieve above-mentioned object of the disclosure, one embodiment of the disclosure provides a method of manufacturing a display panel, including steps of:

Providing a substrate;

Forming a thin film transistor layer on the substrate;

Forming a light emitting device layer on the thin film transistor layer, wherein the light emitting device layer includes an anode layer, the anode layer includes at least one metal layer, and the at least one metal layer in the anode layer includes at least two different kinds of metal grains; and

Forming a thin film encapsulation layer on the light emitting device layer.

In one embodiment of the disclosure, the step of forming a light emitting device layer on the thin film transistor layer further includes steps of:

Forming the anode layer on the thin film transistor layer;

Forming a light emitting layer on the anode layer; and

Forming a cathode layer on the light emitting layer, wherein the step of forming the anode layer on the thin film transistor layer includes steps of:

Forming a first metal layer on the thin film transistor layer;

Forming a second metal layer on the first metal layer; and

Forming a third metal layer on the second metal layer, wherein at least one of the first metal layer, the second metal layer, and the third metal layer includes at least two different kinds of metal grains.

In one embodiment of the disclosure, the step of forming a third metal layer on the second metal layer further includes steps of:

Turning the substrate where the first metal layer and the second metal layer are formed on to form an included angle θ between a deposition direction of a deposition source and a surface of the substrate, wherein the included angle θ is larger than 0 degree and less than 45 degree; and

Forming the third metal layer on the second metal layer, wherein the third metal layer includes at least two different kinds of metal grains.

In one embodiment of the disclosure, a material of each of the first metal layer and the third metal layer includes a combination of aluminum and zinc oxide.

In one embodiment of the disclosure, a material of the second metal layer includes one of aluminum, silver, and gold, or a combination of at least two of aluminum, silver, and gold.

In one embodiment of the disclosure, a thickness of the first metal layer is from 10 nm to 100 nm, a thickness of the second metal layer is from 5 nm to 20 nm, and a thickness of the third metal layer is from 10 nm to 100 nm.

Another embodiment of the disclosure provides a display panel, including a substrate, a thin film transistor layer disposed on the substrate, a light emitting device layer disposed on the thin film transistor layer, and a thin film encapsulation layer disposed on the light emitting device layer.

The light emitting device layer includes an anode layer, and the anode layer includes at least one metal layer.

The at least one metal layer of the anode layer includes at least two different kinds of metal grains.

In one embodiment of the disclosure, the anode layer further includes a first metal layer disposed on the thin film transistor layer, a second metal layer disposed on the first metal layer, and a third metal layer disposed on the second metal layer.

At least one of the first metal layer, second metal layer, and third metal layer includes at least two different kinds metal grains.

In one embodiment of the disclosure, the third metal layer includes at least two different kinds of metal grains.

The third metal layer are formed by metal sputtering process after turning the substrate where the first metal layer and the second metal layer are formed on to form an included angle θ between a deposition direction of a deposition source and a surface of the substrate, wherein the included angle θ is larger than 0 degree and less than 45 degree.

In one embodiment of the disclosure, a material of each of the first metal layer and the third metal layer includes a combination of aluminum and zinc oxide.

In one embodiment of the disclosure, a material of the second metal layer includes one of aluminum, silver, and gold, or a combination of at least two of aluminum, silver, and gold.

In one embodiment of the disclosure, a thickness of the first metal layer is from 10 nm to 100 nm, a thickness of the second metal layer is from 5 nm to 20 nm, and a thickness of the third metal layer is from 10 nm to 100 nm.

Furthermore, another embodiment of the disclosure provides a display module including a display panel, a touch layer, a polaroid layer, and a cover layer. The touch layer, the polaroid layer, and the cover layer are disposed on the display panel. The display panel includes a substrate, a thin film transistor layer disposed on the substrate, a light emitting device layer disposed on the thin film transistor layer, and a thin film encapsulation layer disposed on the light emitting device layer.

The light emitting device layer includes an anode layer, the anode layer includes at least one metal layer, and the at least one metal layer of the anode layer includes at least two different kinds of metal grains.

In one embodiment of the disclosure, the anode layer further includes a first metal layer disposed on the thin film transistor layer, a second metal layer disposed on the first metal layer, and a third metal layer disposed on the second metal layer.

At least one of the first metal layer, second metal layer, and third metal layer includes at least two different kinds metal grains.

In one embodiment of the disclosure, the third metal layer includes at least two different kinds of metal grains.

The third metal layer are formed by metal sputtering process after turning the substrate where the first metal layer and the second metal layer are formed on to form an included angle θ between a deposition direction of a deposition source and a surface of the substrate, wherein the included angle θ is larger than 0 degree and less than 45 degree.

In one embodiment of the disclosure, a material of each the first metal layer and the third metal layer includes a combination of aluminum and zinc oxide.

In one embodiment of the disclosure, a material of the second metal layer includes one of aluminum, silver, and gold, or a combination of at least two of aluminum, silver, and gold.

In one embodiment of the disclosure, a thickness of the first metal layer is from 10 nm to 100 nm, a thickness of the second metal layer is from 5 nm to 20 nm, and a thickness of the third metal layer is from 10 nm to 100 nm.

In comparison with the prior art, the embodiments of the disclosure improve the optical performance of the anode layer, improves the efficiency of the OLED device, and increases the lifetime of the OLED device by using different deposition rates to form an anode layer including at least two different kinds of metal grains.

### BRIEF DESCRIPTION OF THE DRAWINGS

FIG. 1 is a schematic flow chart showing a method of manufacturing a display panel according to one embodiment of the disclosure.

FIG. 2 is a schematic cross-sectional view of a display panel according to one embodiment of the disclosure.

FIG. 3 is a schematic cross-sectional view of an anode layer of a display panel according to one embodiment of the disclosure.

FIG. 4 is a schematic view showing a process for forming an anode layer in a display panel according to one embodiment of the disclosure.

### DETAILED DESCRIPTION OF THE PREFERRED EMBODIMENTS

The following description of the embodiments is provided by reference to the following drawings and illustrates the specific embodiments of the disclosure. Directional terms mentioned in the disclosure, such as “up,” “down,” “top,” “bottom,” “forward,” “backward,” “left,” “right,” “inside,” “outside,” “side,” “peripheral,” “central,” “horizontal,” “peripheral,” “vertical,” “longitudinal,” “axial,” “radial,” “uppermost” or “lowermost,” etc., are merely indicated the direction of the drawings. Therefore, the directional terms are used for illustrating and understanding of the application rather than limiting thereof.

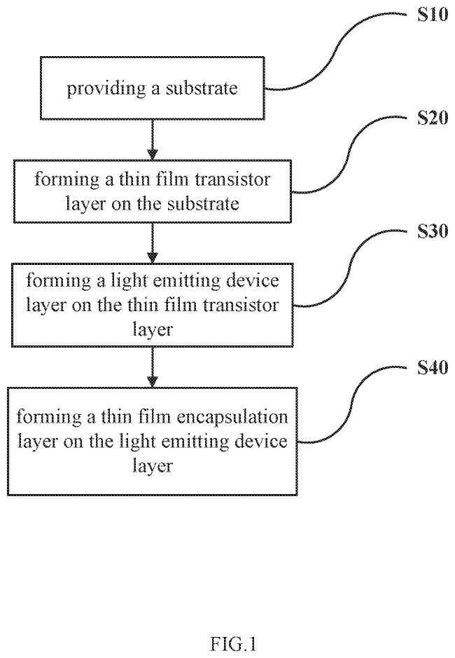

Referring to FIG. 1, FIG. 1 is a schematic flow chart showing a method of manufacturing a display panel according to one embodiment of the disclosure.

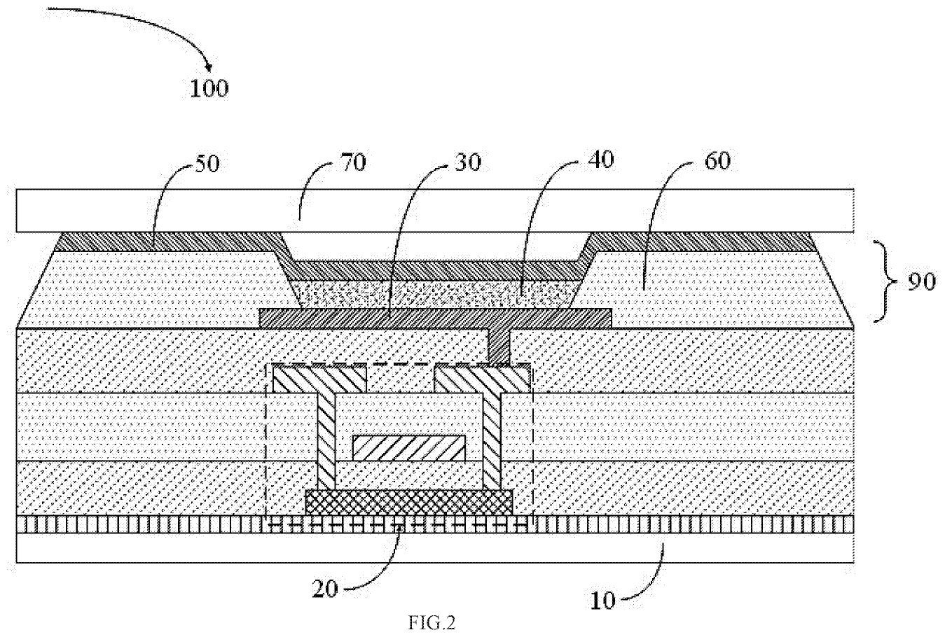

Referring to FIG. 2, FIG. 2 is a schematic cross-sectional view of a display panel according to one embodiment of the disclosure.

A method of manufacturing a display panel includes the steps as following:

At block S10: providing a substrate.

In one embodiment of the disclosure, the substrate 10 can be one of a glass substrate, a quartz substrate, and a resin substrate.

When the display panel 100 is a flexible display panel, the substrate 10 can be a flexible substrate. The material of the flexible substrate can be a polyimide film.

At block S20: forming a thin film transistor layer on the substrate.

In one embodiment of the disclosure, the thin film transistor layer 20 can be one of an etch barrier type, a back channel etch type, or a top gate thin film transistor type structure, and the disclosure is not particularly limited. For example, the top gate thin film transistor type structure may include a buffer layer, an active layer, a gate insulating layer, a gate layer, an interlayer insulating layer, a source/drain layer, and a flat layer.

At block S30: forming a light emitting device layer on the thin film transistor layer.

The light emitting device layer 90 includes an anode layer 30 formed on the thin film transistor layer 20. A light emitting layer 40 is disposed on the anode layer 30. A cathode layer 50 is disposed on the light emitting layer 40.

The anode layer 30 is formed on the planar layer. The anode layer 30 includes at least two anodes arranged in an array. The anode layer 30 is mainly used to provide holes for absorbing electrons.

The light emitting layer 40 is formed on the anode layer 30. The light emitting layer 40 is divided into a plurality of light emitting units by the pixel defining layer 60, and each of the light emitting units corresponds to one of the anodes.

The cathode layer 50 is formed on the light emitting device layer 90. The cathode layer 50 covers the light emitting layer 40 and the pixel defining layer 112 on the array substrate.

In an embodiment, the material of the cathode layer 50 may be one of silver (Ag), aluminum (Al), chromium (Cr), molybdenum (Mo), tungsten (W), titanium (Ti), gold (Au), palladium (Pd) or a combination of at least two of Ag, Al CR, Mo, W, Ti, Au, and Pd.

In one embodiment of the disclosure, the anode layer 30 includes at least one metal layer. The at least one metal layer in the anode layer 30 includes at least two different kinds of metal grains.

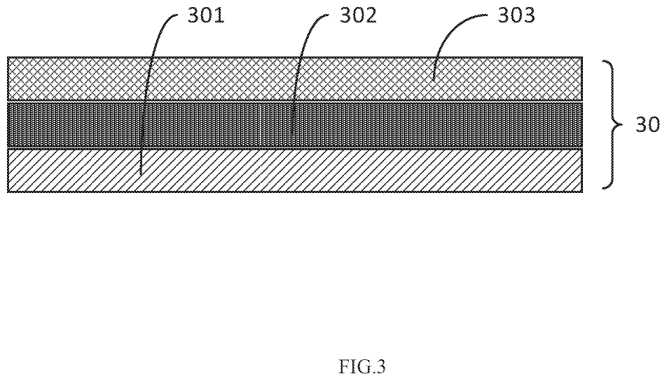

Referring to FIG. 3, FIG. 3 is a schematic cross-sectional view of an anode layer of a display panel according to one embodiment of the disclosure.

In one embodiment of the disclosure, the anode layer 30 further includes a first metal layer 301 disposed on the thin film transistor layer 20, a second metal layer 302 disposed on the first metal layer 301, and a third metal layer 303 disposed on the second metal layer 302.

At least one of the first metal layer 301, second metal layer 302, and third metal layer 303 includes at least two different kinds metal grains.

In one embodiment of the disclosure, the third metal layer 303 includes at least two different kinds of metal grains.

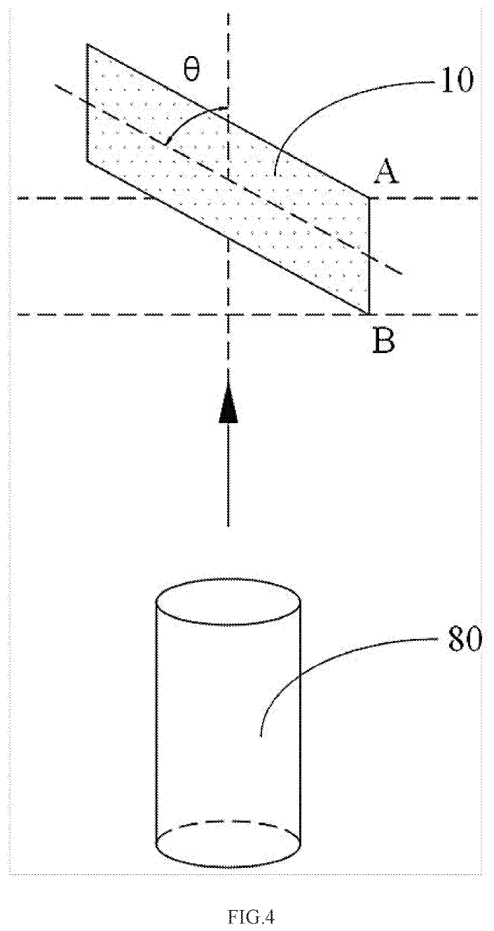

Referring to FIG. 4, FIG. 4 is a schematic view showing a process for forming an anode layer in a display panel according to one embodiment of the disclosure.

The process includes turning the substrate 10 where the first metal layer 301 and the second metal layer 302 are formed on to form an included angle θ between a deposition direction of a deposition source 80 and a surface of the substrate 10, and forming the third metal layer 303 on the second metal layer 302 by sputtering process.

In one embodiment of the disclosure, the included angle θ is larger than 0 degree and less than 45 degree.

In one embodiment of the disclosure, the process for forming the first metal layer and the second metal layer is the same with the technology for forming the third metal layer.

In one embodiment of the disclosure, a material of each of the first metal layer 301 and the third metal layer 303 includes a combination of aluminum and zinc oxide.

In one embodiment of the disclosure, a material of the second metal layer 302 includes one of aluminum, silver, and gold, or a combination of at least two of aluminum, silver, and gold.

In one embodiment of the disclosure, a thickness of the first metal layer 301 is from 10 nm to 100 nm, a thickness of the second metal layer 302 is from 5 nm to 20 nm, and a thickness of the third metal layer 303 is from 10 nm to 100 nm.

Since the substrate 10 is deflected by a certain angle, the different positions of the substrate 10 have different distances from the deposition source 80. Therefore, the rate of grain formation on the position of the substrate 10 adjacent to the deposition source 80 is greater than the rate of grain formation on the position of the substrate 10 far away from the deposition source 80, such that the size and orientation of the metal grains located at different positions on the substrate 10 are different.

In one embodiment of the disclosure, the AZO grains on the side close to the substrate 10 are smaller, and the AZO grains on the side far from the substrate 10 are larger. Thereby, an AZO film having excellent optical properties (conductivity, work function, and transmittance) is formed. Moreover, there is aluminum, silver or gold located between the AZO thin films to form a resonant cavity with the upper and lower AZO thin films to improve the efficiency of the OLED device.

At block S40: forming a thin film encapsulation layer on the light emitting device layer.

The thin film encapsulation layer 70 is formed on the cathode layer 50. The thin film encapsulation layer 70 serves to block water and oxygen and prevent external water vapor from eroding the organic light emitting layer 40.

In one embodiment of the disclosure, the thin film encapsulation layer 70 is formed by alternately superposing at least one organic layer and at least one inorganic layer. Usually, an organic encapsulation layer is located in the middle of the thin film encapsulation layer 70, and an inorganic encapsulation layer is located on both sides of the thin film encapsulation layer 70 to wrap the organic encapsulation layer.

In one embodiment of the disclosure, the thin film encapsulation layer 70 includes an organic layer and two inorganic layers alternately arranged.

Another embodiment of the disclosure provides a display panel including a substrate 10, a thin film transistor layer 20 disposed on the substrate 10, a light emitting device layer 90 disposed on the thin film transistor layer 20, and a thin film encapsulation layer 70 disposed on the light emitting device layer 90.

Referring to FIG. 2, in one embodiment of the disclosure, the substrate 10 can be one of a glass substrate, a quartz substrate, and a resin substrate.

When the display panel 100 is a flexible display panel, the substrate 10 can be a flexible substrate. The material of the flexible substrate can be a polyimide film.

In one embodiment of the disclosure, the thin film transistor layer 20 can be one of an etch barrier type, a back channel etch type, or a top gate thin film transistor type structure, and the disclosure is not particularly limited. For example, the top gate thin film transistor type structure may include a buffer layer, an active layer, a gate insulating layer, a gate layer, an interlayer insulating layer, a source/drain layer, and a flat layer.

The light emitting device layer 90 includes an anode layer 30 formed on the thin film transistor layer 20. A light emitting layer 40 is disposed on the anode layer 30. A cathode layer 50 is disposed on the light emitting layer 40.

In one embodiment of the disclosure, the anode layer 30 includes at least one metal layer. The at least one metal layer in the anode layer 30 includes at least two different kinds of metal grains.

Referring to FIG. 3, FIG. 3 is a schematic cross-sectional view of an anode layer of a display panel according to one embodiment of the disclosure.

In one embodiment of the disclosure, the anode layer 30 further includes a first metal layer 301 disposed on the thin film transistor layer 20, a second metal layer 302 disposed on the first metal layer 301, and a third metal layer 303 disposed on the second metal layer 302.

At least one of the first metal layer 301, second metal layer 302, and third metal layer 303 includes at least two different kinds metal grains.

In one embodiment of the disclosure, the third metal layer 303 includes at least two different kinds of metal grains.

Referring to FIG. 4, FIG. 4 is a schematic view showing a process for forming an anode layer in a display panel according to one embodiment of the disclosure.

The process includes turning the substrate 10 where the first metal layer 301 and the second metal layer 302 are formed on to form an included angle θ between a deposition direction of a deposition source 80 and a surface of the substrate 10, and forming the third metal layer 303 on the second metal layer 302 by sputtering process.

In one embodiment of the disclosure, the included angle θ is larger than 0 degree and less than 45 degree.

In one embodiment of the disclosure, the process for forming the first metal layer and the second metal layer is the same with the technology for forming the third metal layer.

In one embodiment of the disclosure, a material of each of the first metal layer 301 and the third metal layer 303 includes a combination of aluminum and zinc oxide.

In one embodiment of the disclosure, a material of the second metal layer 302 includes one of aluminum, silver, and gold, or a combination of at least two of aluminum, silver, and gold.

In one embodiment of the disclosure, a thickness of the first metal layer 301 is from 10 nm to 100 nm, a thickness of the second metal layer 302 is from 5 nm to 20 nm, and a thickness of the third metal layer 303 is from 10 nm to 100 nm.

Since the substrate 10 is deflected by a certain angle, the different positions of the substrate 10 have different distances from the deposition source 80. Therefore, the rate of grain formation on the position of the substrate 10 adjacent to the deposition source 80 is greater than the rate of grain formation on the position of the substrate 10 far away from the deposition source 80, such that the size and orientation of the metal grains located at different positions on the substrate 10 are different.

In one embodiment of the disclosure, the AZO grains on the side close to the substrate 10 are smaller, and the AZO grains on the side far from the substrate 10 are larger. Thereby, an AZO film having excellent optical properties (conductivity, work function, and transmittance) is formed. Moreover, there is aluminum, silver or gold located between the AZO thin films to form a resonant cavity with the upper and lower AZO thin films to improve the efficiency of the OLED device.

Referring to FIG. 2, the thin film encapsulation layer 70 is formed on the cathode layer 50. The thin film encapsulation layer 70 serves to block water and oxygen and prevent external water vapor from eroding the organic light emitting layer 40.

In one embodiment of the disclosure, the thin film encapsulation layer 70 is formed by alternately superposing at least one organic layer and at least one inorganic layer. Usually, an organic encapsulation layer is located in the middle of the thin film encapsulation layer 70, and an inorganic encapsulation layer is located on both sides of the thin film encapsulation layer 70 to wrap the organic encapsulation layer.

In one embodiment of the disclosure, the thin film encapsulation layer 70 includes an organic layer and two inorganic layers alternately arranged.

Furthermore, another embodiment of the disclosure provides a display module including a display panel, a touch layer, a polaroid layer, and a cover layer. The touch layer, the polaroid layer, and the cover layer are disposed on the display panel. The thin film encapsulation layer is adhered to the touch layer by a first optical adhesive. The polaroid layer is adhered to the cover layer by a second optical adhesive.

The disclosure provides a display panel, a method of manufacturing the same, and a display module having the same. The display panel includes a light emitting device layer. The light emitting device layer includes an anode layer. The anode layer includes at least one metal layer. The at least one metal layer of the anode layer includes at least two different kinds of metal grains. The embodiments of the disclosure improve the optical performance of the anode layer, improves the efficiency of the OLED device, and increases the lifetime of the OLED device by using different deposition rates to form an anode layer including at least two different kinds of metal grains.

The disclosure has been described by the above embodiments, but the embodiments are merely examples for implementing the disclosure. It must be noted that the embodiments do not limit the scope of the invention. In contrast, modifications and equivalent arrangements are intended to be included within the scope of the invention.

What is claimed is:

1. A method of manufacturing a display panel, comprising steps of:
providing a substrate;
forming a thin film transistor layer on the substrate;
forming a light emitting device layer on the thin film transistor layer, wherein the light emitting device layer includes an anode layer, the anode layer includes at least one metal layer, and the at least one metal layer in the anode layer includes at least two different kinds of metal grains; and
forming a thin film encapsulation layer on the light emitting device layer.

2. The method of manufacturing a display panel according to claim 1, wherein the step of forming a light emitting device layer on the thin film transistor layer further comprises steps of:
forming the anode layer on the thin film transistor layer;
forming a light emitting layer on the anode layer; and
forming a cathode layer on the light emitting layer, wherein the step of forming the anode layer on the thin film transistor layer comprises steps of:
forming a first metal layer on the thin film transistor layer;
forming a second metal layer on the first metal layer; and
forming a third metal layer on the second metal layer, wherein at least one of the first metal layer, the second metal layer, and the third metal layer comprises at least two different kinds of metal grains.

3. The method of manufacturing a display panel according to claim 2, wherein the step of forming a third metal layer on the second metal layer further comprises steps of:
turning the substrate where the first metal layer and the second metal layer are formed on to form an included angle θ between a deposition direction of a deposition source and a surface of the substrate, wherein the included angle θ is larger than 0 degree and less than 45 degree; and
forming the third metal layer on the second metal layer, wherein the third metal layer comprises at least two different kinds of metal grains.

4. The method of manufacturing a display panel according to claim 2, wherein a material of each of the first metal layer and the third metal layer comprises a combination of aluminum and zinc oxide.

5. The method of manufacturing a display panel according to claim 2, wherein a material of the second metal layer comprises one of aluminum, silver, and gold, or a combination of at least two of aluminum, silver, and gold.

6. The method of manufacturing a display panel according to claim 2, wherein a thickness of the first metal layer is from 10 nm to 100 nm, a thickness of the second metal layer is from 5 nm to 20 nm, and a thickness of the third metal layer is from 10 nm to 100 nm.

7. A display panel, comprising:
a substrate;
a thin film transistor layer disposed on the substrate;
a light emitting device layer disposed on the thin film transistor layer; and
a thin film encapsulation layer disposed on the light emitting device layer, wherein the light emitting device layer comprises an anode layer, the anode layer comprises at least one metal layer, and the at least one metal layer of the anode layer comprises at least two different kinds of metal grains.

8. The display panel according to claim 7, wherein the anode layer further comprises a first metal layer disposed on the thin film transistor layer, a second metal layer disposed on the first metal layer, and a third metal layer disposed on the second metal layer, and at least one of the first metal layer, second metal layer, and third metal layer comprises at least two different kinds metal grains.

9. The display panel according to claim 8, wherein the third metal layer comprises at least two different kinds of metal grains, and the third metal layer are formed by metal sputtering process after turning the substrate where the first metal layer and the second metal layer are formed on to form an included angle θ between a deposition direction of a deposition source and a surface of the substrate, wherein the included angle θ is larger than 0 degree and less than 45 degree.

10. The display panel according to claim 8, wherein a material of each of the first metal layer and the third metal layer comprises a combination of aluminum and zinc oxide.

11. The display panel according to claim 8, wherein a material of the second metal layer comprises one of aluminum, silver, and gold, or a combination of at least two of aluminum, silver, and gold.

12. The display panel according to claim 8, wherein a thickness of the first metal layer is from 10 nm to 100 nm, a thickness of the second metal layer is from 5 nm to 20 nm, and a thickness of the third metal layer is from 10 nm to 100 nm.

13. A display module, comprising:
a display panel;
a touch layer;
a polaroid layer; and
a cover layer, wherein the touch layer, the polaroid layer, and the cover layer are disposed on the display panel, and the display panel comprises:
a substrate;
a thin film transistor layer disposed on the substrate;
a light emitting device layer disposed on the thin film transistor layer; and
a thin film encapsulation layer disposed on the light emitting device layer, wherein the light emitting device layer comprises an anode layer, the anode layer comprises at least one metal layer, and the at least one metal layer of the anode layer comprises at least two different kinds of metal grains.

14. The display module according to claim 13, wherein the anode layer further comprises a first metal layer disposed on the thin film transistor layer, a second metal layer disposed on the first metal layer, and a third metal layer disposed on the second metal layer, and at least one of the first metal layer, second metal layer, and third metal layer comprises at least two different kinds metal grains.

15. The display module according to claim 14, wherein the third metal layer comprises at least two different kinds of metal grains, and the third metal layer are formed by metal sputtering process after turning the substrate where the first metal layer and the second metal layer are formed on to form an included angle θ between a deposition direction of a deposition source and a surface of the substrate, wherein the included angle θ is larger than 0 degree and less than 45 degree.

16. The display module according to claim 14, wherein a material of each the first metal layer and the third metal layer comprises a combination of aluminum and zinc oxide.

17. The display module according to claim 14, wherein a material of the second metal layer comprises
one of aluminum, silver, and gold, or a combination of at least two of aluminum, silver, and gold.

18. The display module according to claim 14, wherein a thickness of the first metal layer is from 10 nm to 100 nm, a thickness of the second metal layer is from 5 nm to 20 nm, and a thickness of the third metal layer is from 10 nm to 100 nm.
